(19) United States
(12) Patent Application Publication
(10) Pub. No.: US 2026/0233505 A1
(43) Pub. Date: Aug. 13, 2026

(54) METHOD FOR PRODUCING ADHESIVE FILM

(71) Applicant: Resonac Corporation, Tokyo (JP)

(72) Inventor: Tomoyo KANEKO, Tokyo (JP)

(73) Assignee: Resonac Corporation, Tokyo (JP)

(21) Appl. No.: 19/471,845

(22) PCT Filed: Aug. 1, 2024
(86) PCT No.: PCT/JP2024/027570

§ 371 Date: Oct. 2, 2025

(30) Foreign Application Priority Data
Aug. 4, 2023 (JP) 2023-127965

(51) Int. Cl. B32B 38/00

(52) U.S. Cl. CPC B32B 38/0004; B32B 2405/00

(57) ABSTRACT

A method for producing this adhesive film includes: a feeding step of feeding a base material film in a long length provided with a bonding layer on one surface at a predetermined conveyance rate; a cutting step of pre-cutting the bonding layer along a cutting line of a predetermined pattern; and a peeling step of peeling an unnecessary portion of the bonding layer from the one surface of the base material film, and forming a plurality of bonding layers having a pattern based on the cutting line on the one surface of the base material film at predetermined intervals, in which in the cutting step, the unnecessary portion is divided by a division line for dividing the base material film in a width direction.

### TECHNICAL FIELD

The present disclosure relates to a method for producing an adhesive film.

### BACKGROUND ART

Adhesive films in the related art include, for example, a die attach multilayer sheet support disclosed in Patent Literature 1. This die attach multilayer sheet support in the related art includes a base material film in a long length, and a plurality of die attach multilayer films dispersedly arranged in a longitudinal direction of the base material film on one surface of a base material sheet.

The die attach multilayer film includes a die attach film on the base material film side, and a dicing film with the die attach film shape. On one surface of the base material film, protective films identical in thickness to the die attach multilayer film are arranged so as to surround the respective die attach multilayer films. By the arrangement of the protective films, for example, the die attach multilayer film can be protected from a pressure in winding of the adhesive film in a roll shape, so that it is possible to suppress occurrence of deformation of the multilayer film, transfer of winding impressions, and the like.

### Citation List

### Patent Literature

Patent Literature 1: Japanese Unexamined Patent Publication No. 2006-202927

### SUMMARY OF INVENTION

### Technical Problem

For production of the adhesive film described above, for example, a roll-to-roll method is employed. In this method, a base material film having a bonding layer on one surface thereof is fed out from a master roll at a constant conveyance rate, and the bonding layer is pre-cut in a predetermined pattern using a roll blade or the like. After the pre-cutting, an unnecessary portion of the bonding layer is peeled off from the base material film to form the bonding layer with the predetermined pattern on one surface of the base material film.

However, in the process of producing such an adhesive film, depending on the shape of the precut of the bonding layer, the peel strength in the unnecessary portion of the bonding layer may exceed the fracture strength, and, upon peeling of the unnecessary portion of the bonding layer, defects such as fracture or chipping may occur in the unnecessary portion. In a case where such defects occur, it may be impossible to peel the unnecessary portion while winding the film at a constant conveyance rate, leading to a decrease in efficiency of production of the adhesive film.

The present disclosure has been made to solve the above-described problems, and an object of the present disclosure is to provide a method for producing a adhesive film, which enables minimization of fracture and chipping of an unnecessary portion even in a case where the unnecessary portion is peeled while the film is wound at a constant conveyance rate, so that production efficiency is improved.

### Solution to Problem

A method for producing an adhesive film according to an aspect of the present disclosure including: a feeding step of feeding a base material film in a long length provided with a bonding layer on one surface of the base material film at a predetermined conveyance rate; a cutting step of pre-cutting the bonding layer along a cutting line of a predetermined pattern; and a peeling step of peeling an unnecessary portion of the bonding layer from the one surface of the base material film, and forming a plurality of bonding layers having a pattern based on the cutting line on the one surface of the base material film at predetermined intervals, in which in the cutting step, the unnecessary portion is divided by a division line for dividing the base material film in a width direction.

In this method for producing an adhesive film, in the cutting step, when the bonding layer is precut along the cutting line in the predetermined pattern, the unnecessary portion of the bonding layer is divided by the division line in the width direction of the base material film. By preliminarily dividing the unnecessary portion of the bonding layer in the width direction of the base material film, the width of each divided unnecessary portion is reduced, thereby preventing the peel strength of the bonding layer in the unnecessary portion from exceeding the fracture strength. Accordingly, in the peeling step, the fracture and chipping of the unnecessary portion can be minimized even in a case where the unnecessary portion is peeled while the adhesive film is wound at the constant conveyance rate, so that production efficiency of the adhesive film is improved.

In the cutting step, the division line may be formed to connect the cutting lines corresponding to the plurality of bonding layers. In this case, since the divided unnecessary portions are reliably separated from each other, the fracture and chipping of the unnecessary portions can be more reliably minimized.

In the cutting step, the division line may be formed linearly along the extension direction of the base material film. In this case, by forming the division line into a simple shape, the fracture and chipping of the unnecessary portion can be more reliably minimized.

The thickness of the bonding layer may be 10 μm or less. In a case where the thickness of the bonding layer is 5 μm or less, it is conceivable that the peel strength of the bonding layer in the unnecessary portion tends to exceed the fracture strength, and the fracture or chipping of the unnecessary portion frequently occurs during peeling of the unnecessary portion. In contrast, by preliminarily dividing the unnecessary portion using the division line as described above, even in a case where the thickness of the bonding layer is small, the fracture or chipping of the unnecessary portion can be suitably minimized.

### Advantageous Effects of Invention

According to the present disclosure, the fracture and chipping of the unnecessary portion can be minimized even in a case where the unnecessary portion is peeled while the film is wound at a constant conveyance rate, so that production efficiency is improved.

### BRIEF DESCRIPTION OF DRAWINGS

FIG. 1 is a schematic plan view illustrating an adhesive film produced using a method for producing an adhesive film according to an embodiment of the present disclosure.

FIG. 2 is a sectional view taken along line II-II in FIG. 1.

FIG. 3(a) is a schematic plan view illustrating a state of a film in a feeding step, and FIG. 3(b) is a cross-sectional view taken along line III-III in FIG. 3(a).

FIG. 4(a) is a schematic plan view illustrating a state of the film in a cutting step, and FIG. 4(b) is a cross-sectional view taken along line IV-IV in FIG. 4(a).

FIG. 5 is a schematic perspective view illustrating a roll blade used in the cutting step.

FIG. 6(a) is a schematic plan view illustrating a state of the film in a peeling step, and FIG. 6(b) is a cross-sectional view taken along line IV-IV in FIG. 6(a).

FIG. 7 is a schematic perspective view illustrating a configuration of a peeling roller used in the peeling step.

FIG. 8 is a schematic plan view illustrating a state of fracture or chipping of an unnecessary portion that may occur in a comparative example.

FIG. 9(a) to 9(c) are schematic plan views illustrating modifications of the cutting step.

### DESCRIPTION OF EMBODIMENTS

Hereinafter, a suitable embodiment of a method for producing an adhesive film according to an aspect of the present disclosure will be described in detail with reference to the drawings.

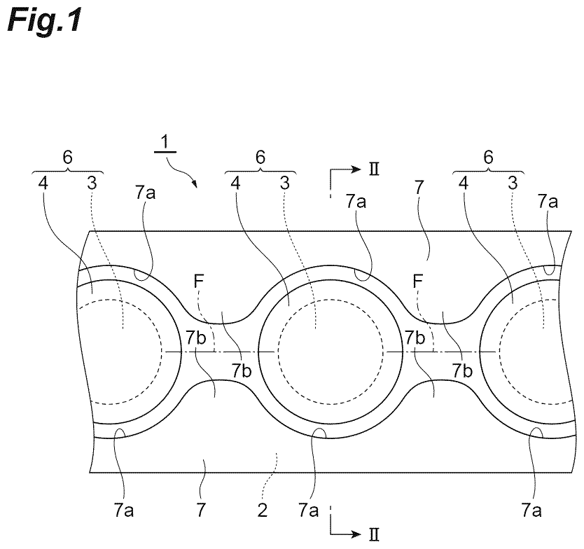

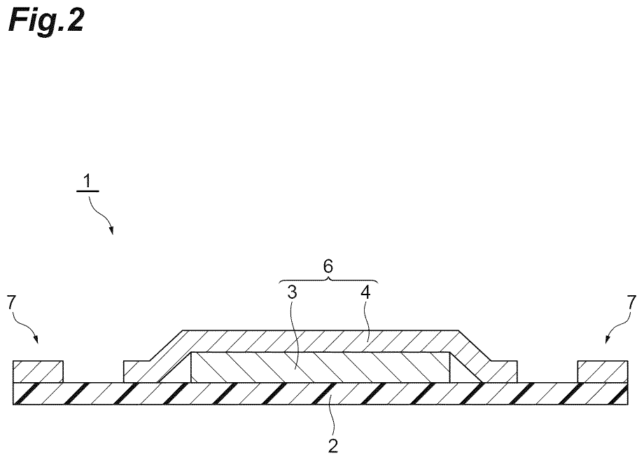

FIG. 1 is a schematic plan view illustrating an adhesive film produced using a method for producing an adhesive film according to an embodiment of the present disclosure. In addition, FIG. 2 is a sectional view taken along line II-II in FIG. 1. An adhesive film 1 illustrated in FIGS. 1 and 2 is used, for example, in a process of producing a semiconductor device. The adhesive film 1 is used, for example, for fixing a semiconductor wafer to a ring frame in a back grinding process, or for bonding a semiconductor chip to a circuit board or the like in a bonding process. The adhesive film 1 may be stored in a state of being wound in a roll shape except when it is used.

As illustrated in FIGS. 1 and 2, the adhesive film 1 includes a base material film 2 in a long length, and a bonding layer 3, and an adhesive film 4, which are provided on one surface of the base material film 2. The bonding layer 3 is disposed on one surface of the base material film 2, and the adhesive film 4 is disposed on the one surface of the base material film 2 to cover the bonding layer 3. Although not illustrated, the adhesive film 4 includes a base material film and an adhesive layer, and is disposed on the one surface of the base material film 2 with the adhesive layer disposed on and facing the bonding layer 3.

The base material film 2 is a film-shaped portion that forms a base of the adhesive film 1. Examples of the constituent material for the base material film 2 include polyethylene terephthalate, and include poly-semi-aromatic ester films such as polybutylene terephthalate and polyethylene naphthalate, wholly aromatic polyester films, liquid-crystalline aromatic polyester films, polyamide films, polyimide films, and polyamideimide films. A surface of the base material film 2 may be subjected to mold release treatment with silicone or the like.

The bonding layer 3 is, for example, a film-shaped part referred to as a die attach film (DAF). In the present embodiment, the thickness of the bonding layer 3 is 5 μm or less. Examples of the constituent material for the bonding layer 3 include thermosetting resins having an electrical insulation property, for example. Examples of the thermosetting resins include epoxy resins, bismaleimide resins, triazine resins, polyimide resins, polyamide resins, cyanoacrylate resins, phenol resins, unsaturated polyester resins, melamine resins, urea resins, polyurethane resins, polyisocyanate resins, furan resins, resorcinol resins, xylene resins, benzoguanamine resins, diallyl phthalate resins, silicone resins, polyvinyl butyral resins, siloxane-modified epoxy resins, siloxane-modified polyamideimide resins, and acrylate resins. These can be used alone, or as a mixture of two or more thereof. The bonding layer 3 may contain acrylic rubber. In this case, the content of the acrylic rubber in the bonding layer 3 may be, for example, 34% or less.

The adhesive film 4 is, for example, a film-shaped part referred to as a dicing tape. The adhesive film 4 includes one or more adhesive layers and one or more base material films. Herein, the adhesive film 4 includes one adhesive layer and one base material film. The thickness of the adhesive film 4 may be, for example, 10 μm to 200 μm, or 20 μm to 150 μm.

Examples of the base material layer of the adhesive film 4 include plastic films such as polyester films, polytetrafluoroethylene films, polyethylene films, polypropylene films and polymethylpentene films. Among them, polyester films are preferable, and polyethylene terephthalate films are more preferable. The base material layer may be a mixture of two or more selected from the above-described materials, or a layer obtained by combining any of the above-described films. The thickness of the base material layer may be, for example, 10 μm to 195 μm, or 20 μm to 150 μm.

It is preferable that the adhesive layer of the adhesive film 4 has adhesive strength at room temperature, and has necessary adhesion strength to an adherend. The adhesive layer preferably has a property of being cured (made less adhesive strength) by a high energy ray such as radiation, or heat, and more preferably can be easily peeled from the base material film 2 and bonding layer 3 without applying a high energy ray such as radiation, or heat. The adhesive layer may be a pressure-sensitive adhesive layer. The adhesive layer can be formed using, for example, an acrylic resin, any of various kinds of synthetic rubber, natural rubber, or a polyimide resin. The thickness of the adhesive layer may be, for example, 5 μm to 100 μm, or 10 μm to 80 μm.

As illustrated in FIG. 1, the above-described bonding layer 3 and adhesive film 4 are separated into a plurality of functional layers 6 and a plurality of protective layers 7 on one surface of the base material film 2. In the present embodiment, the functional layer 6 is a laminate of the bonding layer 3 and the adhesive film 4, and the protective layer 7 is the adhesive film 4 (see FIG. 2). The functional layer 6 and the protective layer 7 are formed by pre-cutting each of the bonding layer 3 and the adhesive film 4 in a predetermined pattern, and then peeling each unnecessary portion from the one surface of the base material film 2.

The plurality of functional layers 6 and 6, the plurality of protective layers 7 and 7, and the functional layers 6 and protective layers 7 are separated from one another as a result of peeling the unnecessary portions after pre-cutting. In the present embodiment, since the unnecessary portions are peeled off using the peeling roller, the separation portions formed by the peeling the unnecessary portions (that is, the separation portion between the plurality of functional layers 6 and 6, the separation portion between the plurality of protective layers 7 and 7, and the separation portion between the functional layer 6 and protective layer 7) are integrally connected in the extension direction of the base material film 2. In the separation portion, by peeling the bonding layer 3 and the adhesive film 4, one surface of the base material film 2 is exposed.

The functional layer 6 is a part that is used in a process of producing semiconductor devices. As illustrated in FIG. 1, the functional layers 6 each have a perfectly circular shape in plan view of the base material film 2, and are arranged apart from with predetermined intervals in the extension direction of the base material film 2. The planar shape of the functional layer 6 is not necessarily a perfectly circular shape, and may be another form of a circular shape such as an elliptical shape or an oval shape. In the functional layer 6, a marker may be added at a predetermined location (for example, the part that extends outward beyond the bonding layer 3) on the adhesive film 4. The marker can be formed using, for example, a screen printing method, a stamping method, an ink-jet method, or the like.

The protective layer 7 is a portion that protects the functional layer 6 from a pressure during winding of the adhesive film 1 in a roll shape. As illustrated in FIGS. 1 and 2, the protective layer 7 extends in the extension direction of the base material film 2 at each of the both edges in the width direction of the base material film 2, to surround each of the functional layers 6. In the present embodiment, the protective layers 7 and 7 at both edges in the width direction of the base material film 2 are symmetrically arranged with respect to the width direction of the base material film 2.

In the example of FIG. 1, the protective layer 7 has a concave portion 7a and a convex portion 7b alternately arranged along the extension direction of the base material film 2. Both the concave portion 7a and the convex portion 7b are oriented with respect to the center in the width direction of the base material film 2. One concave portion 7a of the protective layer 7 and the other concave portion 7a of the protective layer 7 are opposed to each other in the width direction, and one convex portion 7b of the protective layer 7 and the other convex portion 7b of the protective layer 7 are also opposed to each other in the width direction, resulting in the circular functional layer 6 being surrounded by the protective layer 7.

Next, a method for producing the above-described adhesive film 1 will be described.

The method for producing an adhesive film according to the present embodiment includes a feeding step (step S01), a cutting step (step S02), and a peeling step (step S03). In the present embodiment, these steps are performed by a roll-to-roll method.

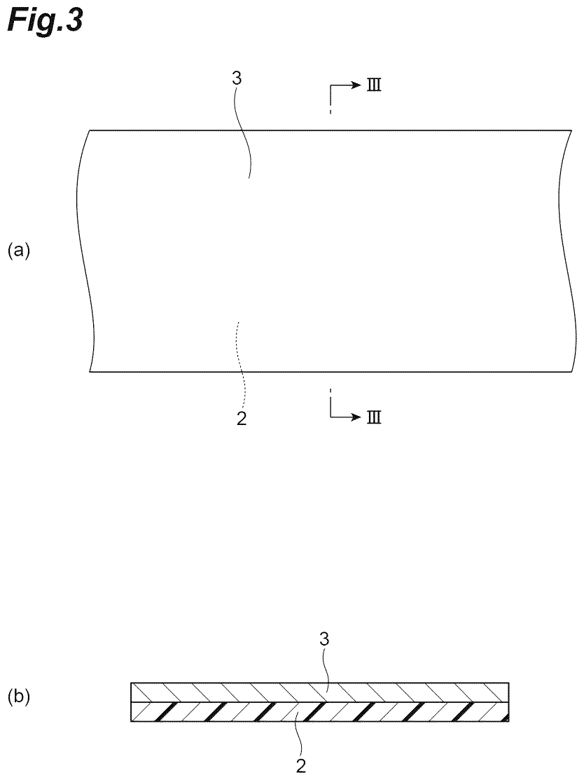

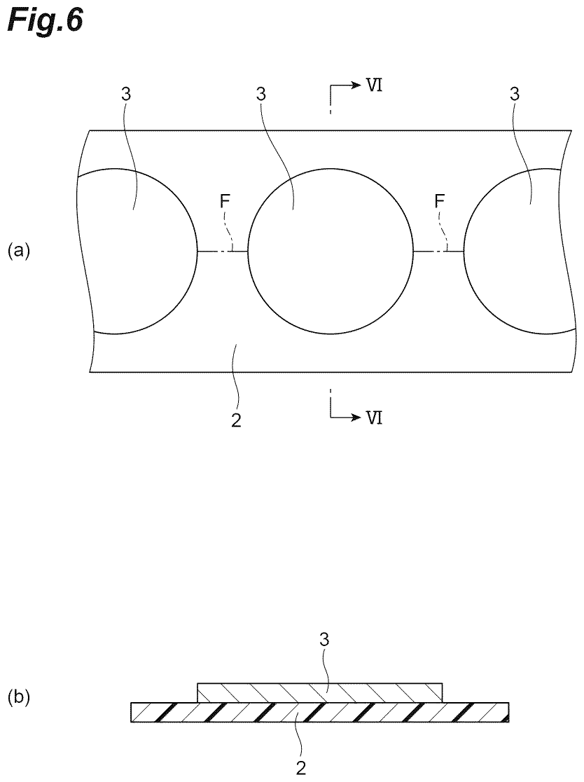

As described in FIG. 3(a) and 3(b), the feeding step S01 is a step of feeding the base material film in a long length with the bonding layer provided on one surface thereof at a predetermined conveyance rate. Herein, a roll of the base material film 2 in a long length with the bonding layer 3 provided on one surface thereof is fed from a feeding roller and conveyed toward the installation position of a roll blade 11 (see FIG. 6), which performs the cutting step S02, while applying a constant tension to the base material film 2 using a plurality of conveying rollers and the like.

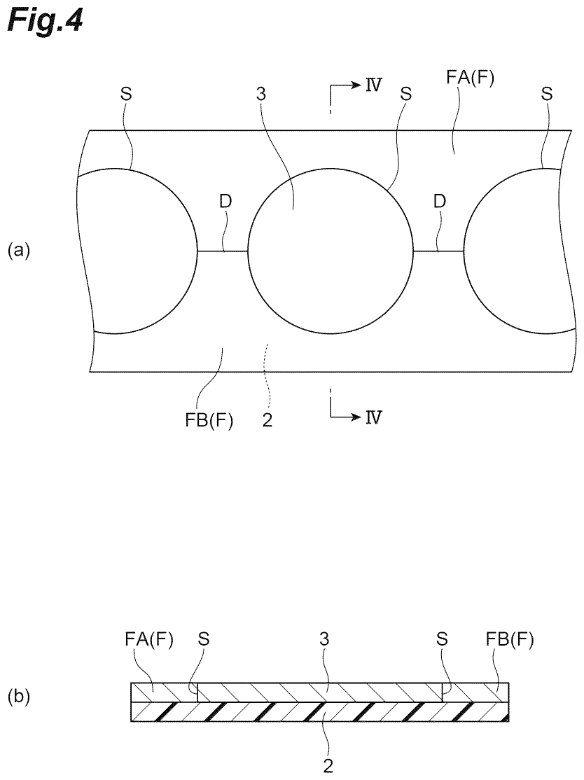

As illustrated in FIGS. 4(a) and 4(b), the cutting step S02 is a step of pre-cutting the bonding layer 3 along a cutting line S of a predetermined pattern. In the cutting step S02, the bonding layer 3 is precut by the circular cutting lines S set at predetermined intervals in the extension direction of the base material film 2 in plan view of the base material film 2 (see FIG. 4(a)). Along the circular cutting line S, the bonding layer 3 constituting the functional layer 6 is finally formed, and a region outside the circular cutting line S is the unnecessary portion F peeled off in the peeling step S03.

In cutting step S02, the unnecessary portion F is divided by a division line D for dividing the base material film 2 in the width direction. Herein, the division line D is formed to connect the circular cutting lines S and S arranged at the predetermined intervals in the extension direction of the base material film 2. In the example of FIG. 4(a), a linear division line D along the extension direction of the base material film 2 is formed at the center of the base material film 2 in the width direction, and the circular cutting lines S and S adjacent to each other in the extension direction of the base material film 2 are connected by the division line D.

The unnecessary portion F is divided by the division line D into an unnecessary portion FA on one side in the width direction of the base material film 2 and an unnecessary portion FB on the other side in the width direction of the base material film 2. Regarding the unnecessary portions FA and FB, the width between the circular cutting lines S arranged in the extension direction of the base material film 2 (the width in the width direction of the base material film 2) is approximately half that of the unnecessary portion F before the division. Therefore, the peeling area of each of the unnecessary portions FA and FB can be reduced as compared with the case where the unnecessary portion F is peeled as it is.

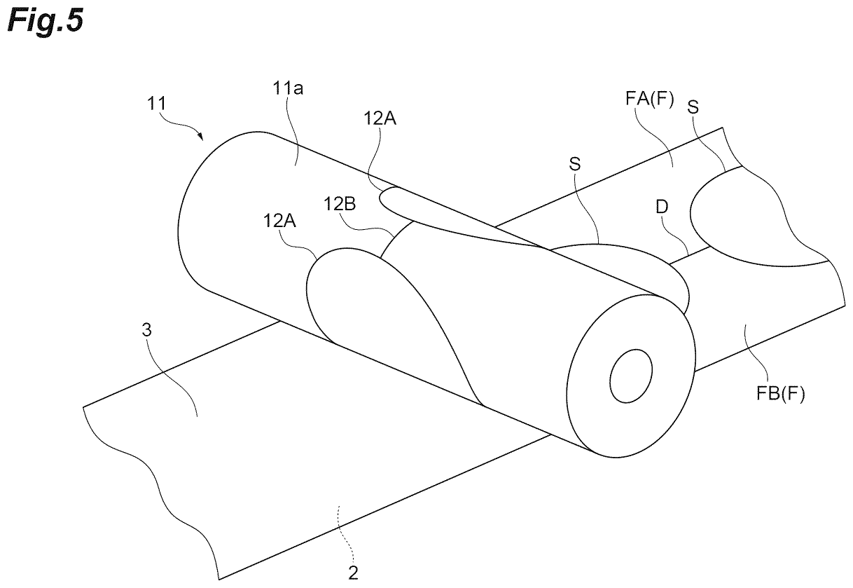

FIG. 5 is a schematic perspective view illustrating the roll blade 11 used in the cutting step S02. As illustrated in FIG. 6, a circumferential surface 11a of the roll blade 11 is provided with a plurality of circular first blades 12A corresponding to the circular cutting lines S set at predetermined intervals, and a linear second blade 12B that connects the adjacent first blades 12A and 12A. In the cutting step S02, the roll blade 11 is pressed against the bonding layer 3 on one surface of the base material film 2 in a long length conveyed at a predetermined conveyance rate while being rotated, and the cutting line S and the division line D are continuously formed on the bonding layer 3 in the extension direction of the base material film 2.

From the viewpoint of more reliably cutting the bonding layer 3, in the cutting step S02, the roll blade 11 may be pressed against the bonding layer 3 on one surface of the base material film 2 in a long length so that the first blades 12A and the second blades 12B reach the one surface of the base material film 2. In this case, cut marks Fa caused by the first blades 12A and the second blades 12B are formed on one surface of the base material film 2 at a depth that does not reach the other surface of the base material film 2. The cut marks Fa may remain on one surface of the base material film 2 after the unnecessary portion F of the bonding layer 3 is peeled off (see FIG. 6(a)). The cut marks Fa may also remain on one surface of the base material film 2 in the adhesive film 1 ultimately obtained (see FIG. 1).

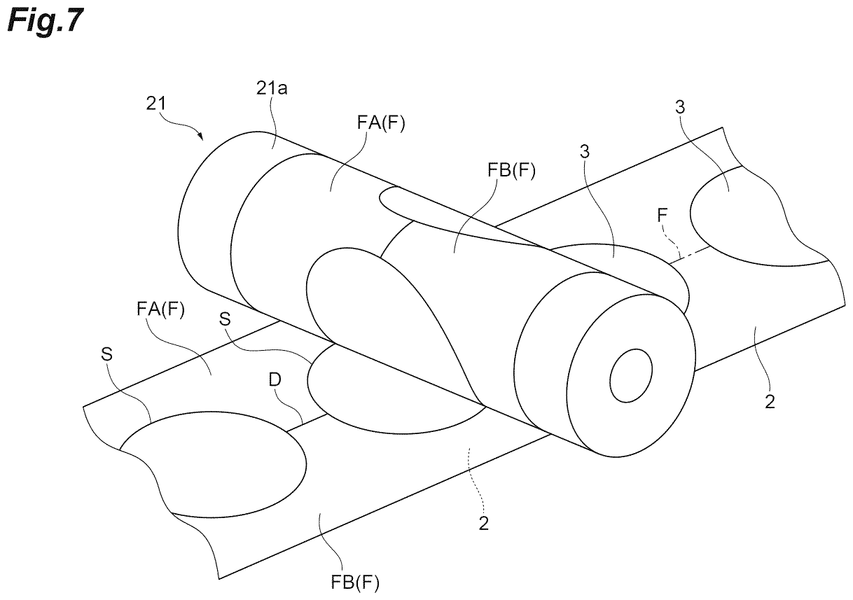

The peeling step S03 is a step of peeling off the unnecessary portion F of the bonding layer 3 from one surface of the base material film 2. In the peeling step S03, since the unnecessary portion F of the bonding layer 3 is peeled off from one surface of the base material film 2, a plurality of bonding layers 3 having a pattern based on the cutting lines S are formed at predetermined intervals on one surface of the base material film 2 as illustrated in FIGS. 6(a) and 6(b). In the present embodiment, the peeling step S03 is performed using, for example, a peeling roller 21 illustrated in FIG. 7. By winding the unnecessary portion F of the bonding layer 3 around the circumferential surface 21a of the peeling roller 21, the unnecessary portion F of the bonding layer 3 is continuously peeled off from one surface of the base material film 2 in a long length conveyed at a predetermined conveyance rate.

As described above, the unnecessary portion F of the bonding layer 3 is divided by the division line D into the unnecessary portion FA on one side of the base material film 2 in the width direction and the unnecessary portion FB on the other side of the base material film 2 in the width direction. Therefore, when the unnecessary portion F of the bonding layer 3 is peeled off using the peeling roller 21, the unnecessary portion FA and the unnecessary portion FB are wound around the peeling roller 21 in a state of being separated from each other.

After the execution of the peeling step S03, a plurality of circular bonding layers 3 are arranged at predetermined intervals in the extension direction of the base material film 2 on one surface of the base material film 2. Thereafter, the adhesive film 4 is laminated over the entire one surface of the base material film 2 so as to cover the circular bonding layers 3, and the adhesive film 4 is pre-cut into a circular shape slightly larger than the bonding layers 3. Then, by peeling off the unnecessary portion of the adhesive film 4 from one surface of the base material film 2 and forming the functional layers 6 and the protective layers 7, the adhesive film 1 illustrated in FIGS. 1 and 2 is obtained.

As described above, in the method for producing an adhesive film, when the bonding layer 3 is pre-cut along the predetermined pattern of the cutting line S in the cutting step S02, the unnecessary portion F of the bonding layer 3 is divided into the unnecessary portions FA and FB by the division line D for dividing the unnecessary portion F in the width direction of the base material film 2.

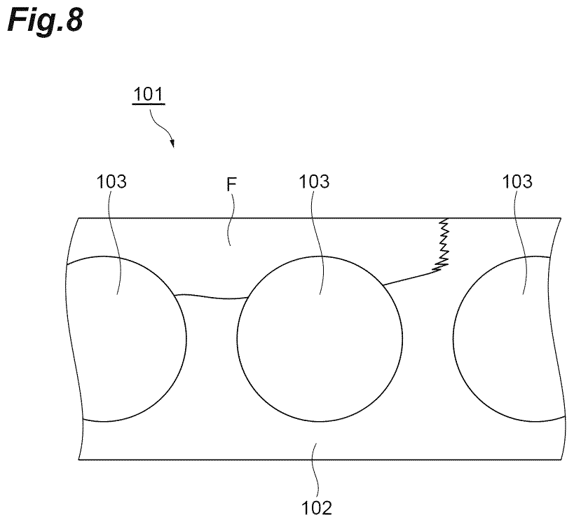

In an adhesive film 101 in which an unnecessary portion F is not divided in a comparative example, it is conceivable that the peel strength of a bonding layer 103 in the unnecessary portion F (the peel strength with respect to one surface of a base material film 102) may exceed its fracture strength. In a case where the peel strength of the bonding layer 103 in the unnecessary portion F exceeds its fracture strength, defects such as fracture or chipping may occur in the unnecessary portion F during the peeling of the unnecessary portion F by the peeling roller 21 in the peeling step S03, and, for example, as illustrated in FIG. 8, a part of the unnecessary portion F may remain on one surface of the base material film 102. In a case where such defects occur, it may be impossible to peel the unnecessary portion while winding the film at a constant conveyance rate, leading to a decrease in efficiency of production of the adhesive film.

To address this problem, in the present embodiment, by preliminarily dividing the unnecessary portion F of the bonding layer 3 in the width direction of the base material film 2, the width of each of the divided unnecessary portions FA and FB is reduced, thereby preventing the peel strength of the bonding layer 3 in the unnecessary portions FA and FB from exceeding the fracture strength. Accordingly, in the peeling step S03, the fracture and chipping of the unnecessary portions FA and FB can be minimized even in a case where the unnecessary portions FA and FB are peeled while the film is wound at a constant conveyance rate, so that production efficiency of the adhesive film 1 is improved.

In the present embodiment, in the cutting step S02, the division line D is formed to connect the cutting lines S and S corresponding to the plurality of bonding layers 3. As a result, the divided unnecessary portions FA and FB are reliably separated from each other, so that the fracture and chipping of the unnecessary portions FA and FB can be more reliably minimized. In the present embodiment, in the cutting step S02, the division line D is formed linearly along the extension direction of the base material film 2. In this way, by forming the division line D into a simple shape, it is possible to more reliably minimize the fracture and chipping of the unnecessary portions FA and FB.

In the present embodiment, the thickness of the bonding layer 3 is 5 μm or less. When the thickness of the bonding layer 3 is 5 μm or less, the peel strength of the bonding layer 3 in the unnecessary portion F tends to exceed the fracture strength, and it is conceivable that fracture or chipping of the unnecessary portion F frequently occurs during peeling of the unnecessary portion F. In contrast, by preliminarily dividing the unnecessary portion F into the unnecessary portions FA and FB using the division line D as described above, even in a case where the thickness of the bonding layer 3 is small, fracture or chipping of the unnecessary portions FA and FB can be suitably suppressed.

In the present embodiment, the bonding layer 3 contains an acrylic rubber, and the content of the acrylic rubber in the bonding layer 3 is 34% or less. In a case where the content of the acrylic rubber in the bonding layer 3 is 34% or less, the peel strength of the bonding layer 3 in the unnecessary portion F tends to exceed the fracture strength, and it is conceivable that the fracture or chipping of the unnecessary portion F frequently occurs during peeling of the unnecessary portion F. In contrast, as described above, by dividing the unnecessary portion F into the unnecessary portions FA and FB in advance using the division line D, it is possible to suitably minimize the fracture and chipping of the unnecessary portions FA and FB even in a case where the content of the acrylic rubber in the bonding layer 3 is small.

The present disclosure is not limited to the embodiment described above. For example, in the above embodiment, the linear division line D is formed to connect the cutting lines S corresponding to the plurality of bonding layers 3; however, the shape of the division line D is not limited to this configuration, and various modifications can be applied, as long as the peel strength of the bonding layer 3 in the unnecessary portion F is reduced relative to its fracture strength.

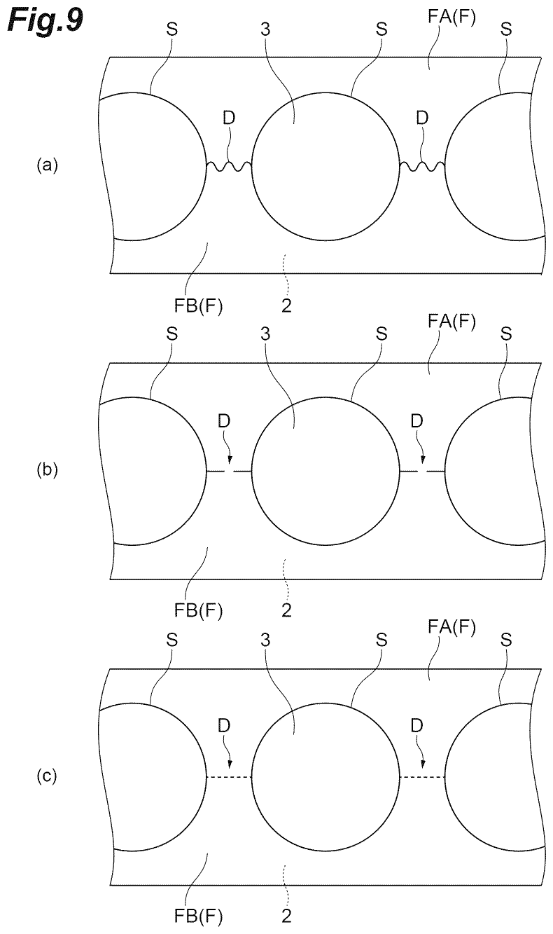

For example, as illustrated in FIG. 9(a), a wavy division line D may be formed to connect the cutting lines S corresponding to the plurality of bonding layers 3. The shape of the division line D is not limited to the wavy line shape, and may be other shapes such as a saw blade shape and a comb blade shape. In a case where the cutting line S is linear, the cutting line S may extend obliquely with respect to the extension direction of the base material film 2.

The division line D is not necessarily continuous between the cutting lines S and S adjacent in the extension direction of the base material film 2. For example, as illustrated in FIG. 9(b), the division line D may be interrupted at the center between the cutting lines S and S adjacent in the extension direction of the base material film 2. The division line D may have a perforated shape, for example, as illustrated in FIG. 9(c). In FIGS. 9(b) and 9(c), the unnecessary portion F may be divided into the unnecessary portions FA and FB along the division line D during the execution of the peeling step S03. Also in such an embodiment, the same effects as those of the above-described embodiment are obtained.

### REFERENCE SIGNS LIST

1 Adhesive film
2 Base material film
3 Bonding layer
F (FA, FB) Unnecessary portion
S Cutting line
D Division line

1. A method for producing an adhesive film comprising:
feeding a base material film in a long length provided with a bonding layer on one surface of the base material film at a predetermined conveyance rate;
pre-cutting the bonding layer along a cutting line of a predetermined pattern; and
peeling an unnecessary portion of the bonding layer from the one surface of the base material film, and forming a plurality of bonding layers having a pattern based on the cutting line on the one surface of the base material film at predetermined intervals, wherein
in the pre-cutting, the unnecessary portion is divided by a division line for dividing the base material film in a width direction.

2. The method for producing an adhesive film according to claim 1, wherein
in the pre-cutting, the division line is formed to connect the cutting lines corresponding to the plurality of bonding layers.

3. The method for producing an adhesive film according to claim 1, wherein
in the pre-cutting, the division line is formed linearly along an extension direction of the base material film.

4. The method for producing an adhesive film according to claim 1, wherein
the bonding layer has a thickness of 10 μm or less.
